(19) United States
(12) Patent Application Publication
(10) Pub. No.: US 2026/0262510 A1
(43) Pub. Date: Sep. 3, 2026

(54) SEMICONDUCTOR PACKAGE METAL LAYER CAPACITORS

(71) Applicant: TEXAS INSTRUMENTS INCORPORATED, Dallas, TX (US)

(72) Inventor: Enis TUNCER, Dallas, TX (US)

(21) Appl. No.: 19/067,600

(22) Filed: Feb. 28, 2025

(51) Int. Cl. H10W 70/60; H10D 1/68; H10W 70/05; H10W 70/65; H10W 70/685; H10W 90/00; H10W 74/10

(52) U.S. Cl. CPC H10W 70/611; H10D 1/692; H10W 70/05; H10W 70/65; H10W 70/685; H10W 90/00; H10W 74/117

(57) ABSTRACT

In examples, a semiconductor package includes a first semiconductor die, a second semiconductor die, and a mold compound covering the first and second semiconductor dies. The semiconductor package also includes a multi-layer substrate coupled to the first and second semiconductor dies and having a top surface contacting the mold compound. The multi-layer substrate comprises multiple metal members in multiple horizontal planes within the multi-layer substrate and dielectric material in between the multiple metal members. The multiple metal members and the dielectric material form multiple capacitors.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure may be subsequently covered with a mold compound to produce a package.

### SUMMARY

In examples, a semiconductor package includes a first semiconductor die, a second semiconductor die, and a mold compound covering the first and second semiconductor dies. The semiconductor package also includes a multi-layer substrate coupled to the first and second semiconductor dies and having a top surface contacting the mold compound. The multi-layer substrate comprises multiple metal members in multiple horizontal planes within the multi-layer substrate and dielectric material in between the multiple metal members. The multiple metal members and the dielectric material form multiple capacitors.

In examples, a method for manufacturing a semiconductor package includes forming a multi-layer substrate by iteratively plating a metal layer using a patterned photoresist, applying dielectric material to the metal layer, and thinning the dielectric material. The multi-layer substrate comprises multiple metal members in multiple horizontal planes within the multi-layer substrate and the dielectric material in between the multiple metal members. The multiple metal members and the dielectric material form multiple capacitors. The method also includes coupling a first semiconductor die to the multi-layer substrate, coupling a second semiconductor die to the multi-layer substrate, and applying a mold compound to the multi-layer substrate and the first and second semiconductor dies.

### BRIEF DESCRIPTION OF THE DRAWINGS

FIGS. 1A, 1B, and 1C are profile cross-sectional, top-down, and perspective views of a semiconductor package including metal layer capacitors, in accordance with various examples.

FIGS. 2A, 2B, and 2C are profile cross-sectional, top-down, and perspective views of a semiconductor package including metal layer capacitors, in accordance with various examples.

FIG. 3 is a graph depicting the behavior of a semiconductor package including metal layer capacitors, in accordance with various examples.

FIG. 4 is a schematic diagram depicting the electric field behavior of a semiconductor package including metal layer capacitors, in accordance with various examples.

FIG. 5 is a graph depicting the behavior of a semiconductor package including metal layer capacitors, in accordance with various examples.

FIG. 6 is a schematic diagram depicting the electric field behavior of a semiconductor package including metal layer capacitors, in accordance with various examples.

FIGS. 7, 8, 9, and 10 are graphs depicting the behavior of a semiconductor package including metal layer capacitors, in accordance with various examples.

FIG. 11 is a flow diagram of a method for manufacturing a semiconductor package including metal layer capacitors, in accordance with various examples.

FIGS. 12A, 12B, 12C, 12D, 12E, 12F, 12G, 12H, 12I, 12J, and 12K are a process flow of a method for manufacturing a semiconductor package including metal layer capacitors, in accordance with various examples.

FIG. 13 is a block diagram of an electronic device including a semiconductor package having metal layer capacitors, in accordance with various examples.

### DETAILED DESCRIPTION

Semiconductor wafer-level capacitors occupy a significant portion of semiconductor die area, which limits available space for other circuit components and constrains opportunities for further miniaturization. In reinforced isolation technologies, wire bonding is used between capacitor dies, introducing several challenges in both manufacturing and performance. For example, the formation of bond wire loops introduces variability in bond wire loop profile and die-to-wire distances, which directly impact the local electric field distribution. For instance, such variability can lead to regions of elevated electric field intensity, increasing the risk of dielectric stress and potential failure. Additionally, bond wire loops can develop kinks at which electric fields become concentrated. These concentrated electric fields not only degrade insulation integrity over time but may also lead to early breakdown under high-voltage operation. Compounding these technical challenges, the diameter of the bond wire imposes mechanical constraints, particularly with respect to the surrounding mold compound, because the stress generated by the wire bond within the mold compound introduces localized mechanical strain, increasing the likelihood of microcracks, delamination, or other structural defects that compromise long-term reliability.

Beyond these electrical and mechanical challenges, the wire loop approach imposes further constraints on electric field mitigation strategies. Bond wires offer limited flexibility in shaping or redirecting electric field distributions, making it more difficult to optimize insulation performance. This constraint is particularly significant in high-voltage applications, in which precise electric field control is necessary to prevent premature dielectric failure. Additionally, the current thickness of isolation semiconductor packages in Small Outline Integrated Circuit (SOIC) configurations, approximately 2.2 mm, presents another limitation. While this thickness is necessary to maintain insulation integrity, this thickness restricts the reduction of overall package size for applications in which space efficiency is critical.

This description presents various examples of semiconductor packages that mitigate the technical challenges described above. Specifically, each example semiconductor package described herein includes capacitors formed by metal layers in a substrate of the package. Critically, the capacitors do not include bond wires and do not couple to bond wires. Rather, each pair of the metal layers operates as the metal plates of a capacitor, and a dielectric layer in between the metal layers operates as the capacitor dielectric. The metal layers in each pair of metal layers are coupled to different semiconductor dies in the semiconductor package through a network of metal layers and metal vias to facilitate the provision of electrical signals to the metal layers of the capacitor, thereby enabling the semiconductor dies to operate the capacitor. In example semiconductor packages, multiple pairs (e.g., four or more) of such metal layer capacitors are included in the package substrate, which reduces the extent to which the electric field(s) generated by the capacitors extend outside of the package. By eliminating bond wires from the package, the technical problems described above as being associated with bond wires are eliminated completely, and the package thickness also is substantially reduced. Various example packages are now described with reference to the drawings.

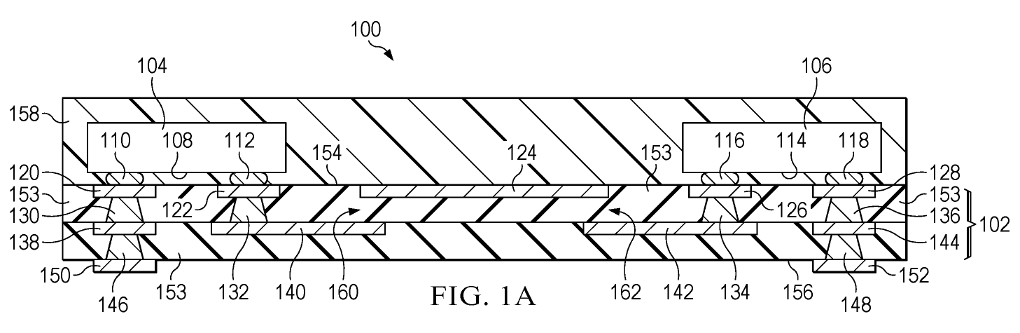

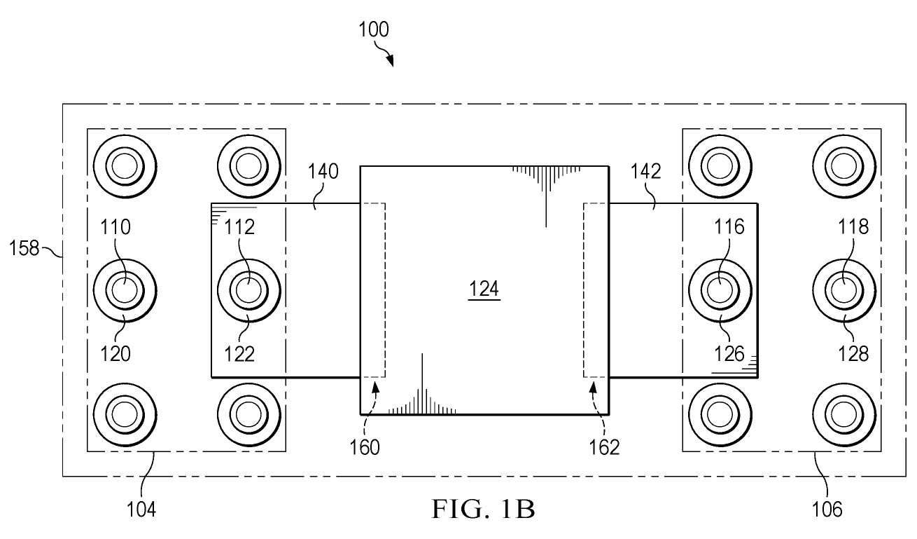

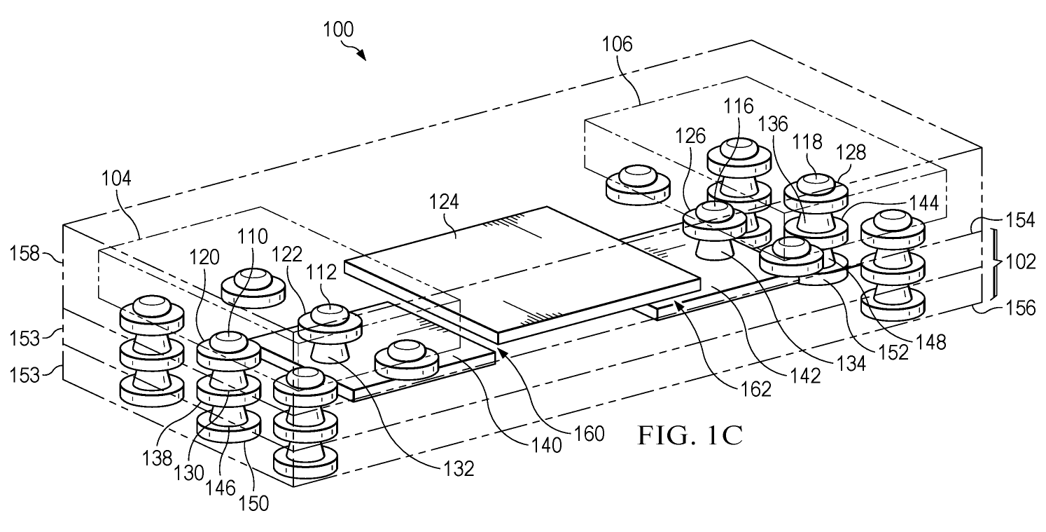

FIGS. 1A, 1B, and 1C are profile cross-sectional, top-down, and perspective views of a semiconductor package 100 including metal layer capacitors, in accordance with various examples. The example semiconductor package 100 includes a substrate 102 and semiconductor dies 104 and 106 coupled to the substrate 102. Although two semiconductor dies 104, 106 are shown and described, any number of semiconductor dies may be included in the semiconductor package 100. The semiconductor die 104 includes a device side 108 in which circuitry is formed. The device side 108 is coupled to the substrate 102 by solder bumps 110 and 112. The semiconductor die 106 includes a device side 114 in which circuitry is formed. The device side 114 is coupled to the substrate 102 by solder bumps 116 and 118. The various semiconductor dies (e.g., semiconductor dies 104, 106) are configured to operate in separate voltage domains and thus are electrically isolated from each other.

The substrate 102 includes multiple metal layers that are connected by metal vias extending in the vertical direction. At least some of the metal layers operate as capacitors. More specifically, the substrate 102 includes a first metal layer including metal members 120, 122, 124, 126, and 128. The first metal layer extends in a horizontal direction. The metal members 120, 122, 124, 126, and 128 are considered to be in the first metal layer because these metal members are coplanar with each other. The substrate 102 includes a metal via 130 coupled to the metal member 120; a metal via 132 coupled to the metal member 122; a metal via 134 coupled to the metal member 126; and a metal via 136 coupled to the metal member 128. The substrate 102 includes a second metal layer including metal members 138, 140, 142, and 144. The second metal layer extends in a horizontal direction. The metal members 138, 140, 142, and 144 are considered to be in the second metal layer because these metal members are coplanar with each other. The metal member 138 is coupled to the metal via 130; the metal member 140 is coupled to the metal via 132; the metal member 142 is coupled to the metal via 134; and the metal member 144 is coupled to the metal via 136. The substrate 102 includes a metal via 146 coupled to the metal member 138, and a metal via 148 coupled to the metal member 144. The substrate 102 also includes a third metal layer including metal members 150 and 152, both of which extend vertically downward from a bottom surface 156 of the substrate 102. The third metal layer extends in a horizontal direction. The metal member 150 is coupled to the metal via 146, and the metal member 152 is coupled to the metal via 148. The substrate 102 includes a dielectric 153 (e.g., a build-up film such as AJINOMOTO® build-up film (ABF), pre-preg) in between the first and second metal layers, in between the second and third metal layers, in between coplanar metal vias (e.g., in between metal vias 130, 132, 134, and 136, and in between metal vias 146 and 148), and in between the metal members of the same metal layer. The dielectric 153 physically contacts the various metal members and vias of the substrate 102, as shown. The substrate 102 has a top surface 154 that is opposite the bottom surface 156. The first metal layer is coincident with the top surface 154, and the third metal layer is coincident with the bottom surface 156. Although three distinct metal layers are shown in FIGS. 1A-1C, in examples, any suitable number of metal layers may be included. A mold compound 158 physically contacts the semiconductor dies 104 and 106 and the top surface 154 of the substrate 102, as shown.

The substrate 102 includes multiple capacitors 160 and 162. The capacitor 160 includes the metal members 124 (from the first metal layer, and operating as a first capacitor plate) and 140 (from the second metal layer, and operating as a second capacitor plate), as well as the dielectric 153 therebetween. The capacitor 162 includes the metal members 124 (from the first metal layer, and operating as a third capacitor plate) and 142 (from the second metal layer, and operating as a fourth capacitor plate), as well as the dielectric 153 therebetween.

The semiconductor die 104 is configured to access and operate the capacitor 160 by way of the device side 108, the solder bump 112, the metal member 122, the metal via 132, and the metal member 140. The metal members 140, 124 and the dielectric 153 form the capacitor 160, and thus the semiconductor die 104, and more specifically the circuitry on the device side 108 of the semiconductor die 104, is able to access the capacitor 160 through this pathway. Similarly, the semiconductor die 106 is configured to access and operate the capacitor 162 by way of the device side 114, the solder bump 116, the metal member 126, the metal via 134, and the metal member 142. The metal members 142, 124 and the dielectric 153 form the capacitor 162, and thus the semiconductor die 106, and more specifically the circuitry on the device side 114 of the semiconductor die 106, is able to access the capacitor 162 through this pathway.

The capacitors 160, 162 are entirely, or approximately entirely, contained within the substrate 102. Thus, no die space is used for the capacitors, and no space outside of the semiconductor package 100 is used for the capacitors. Furthermore, no bond wires are used for the capacitors 160, 162, nor are any bond wires used to connect the capacitors 160, 162 to the semiconductor dies 104, 106. Thus, all of the technical challenges described above with respect to bond wires are eliminated.

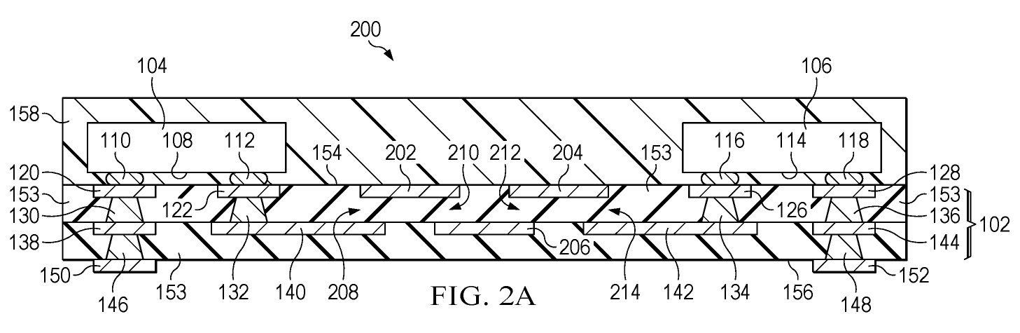

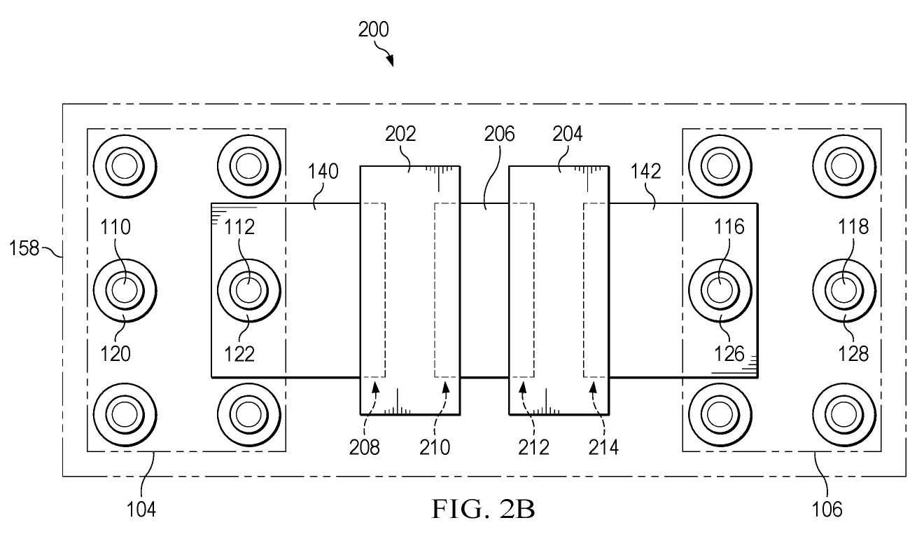

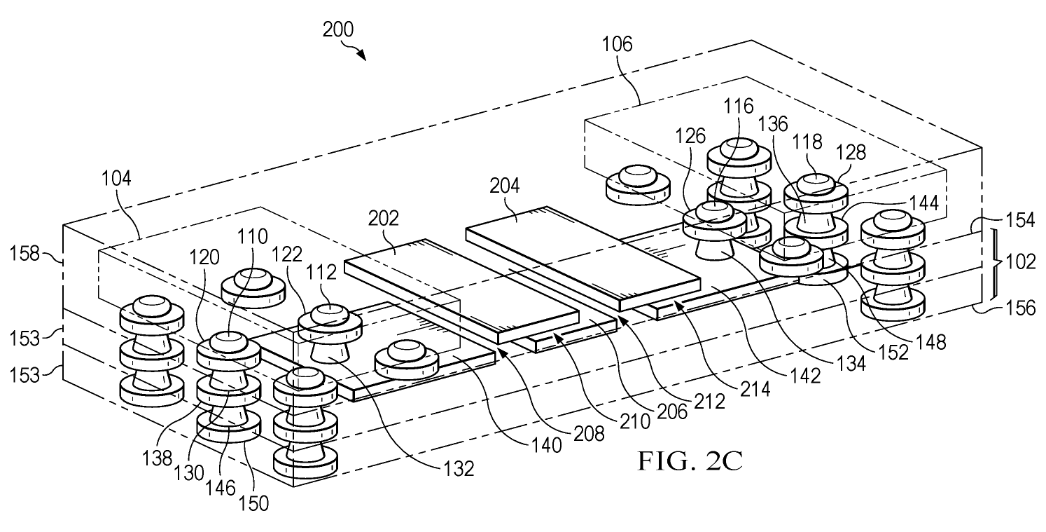

The electric field generated by n capacitors within the substrate 102 extends beyond the bottom surface 156 by x. In contrast, the electric field generated by a number of capacitors in the substrate 102 greater than n extends beyond the bottom surface 156 by a distance less than x. Consequently, to contain the electric field(s) of the capacitors in the substrate 102 within the substrate 102, or at least within a critical distance of the bottom surface 156, a greater number of capacitors is useful. All else being equal, the greater the number of capacitors in the substrate 102, the shorter the reach of the electric field(s) outside of the substrate 102. FIGS. 2A, 2B, and 2C are profile cross-sectional, top-down, and perspective views of a semiconductor package 200 including metal layer capacitors, in accordance with various examples. More specifically, the semiconductor package 200 is identical to the semiconductor package 100 of FIGS. 1A-1C, except that the semiconductor package 200 includes a greater number of capacitors than does the semiconductor package 100. In the semiconductor package 200, the first metal layer in the substrate 102 includes two metal members 202, 204 in lieu of the metal member 124. Furthermore, in the semiconductor package 200, the second metal layer in the substrate 102 includes a third metal member 206 in between the metal members 140, 142. Consequently, a capacitor 208 is formed by the metal members 202, 140 operating as the capacitor plates and the dielectric 153 operating as the capacitor dielectric. A capacitor 210 is formed by the metal members 202, 206 operating as the capacitor plates and the dielectric 153 operating as the capacitor dielectric. A capacitor 212 is formed by the metal members 206, 204 operating as the capacitor plates and the dielectric 153 operating as the capacitor dielectric. A capacitor 214 is formed by the metal members 204, 142 operating as the capacitor plates and the dielectric 153 operating as the capacitor dielectric. In this way, a total of four capacitors are present in the substrate 102, which is greater in number than the two capacitors that are present in the semiconductor package 100, leading to a desirable reduction in the excursion of the electric field(s) outside of the substrate 102. In examples, the various metal members shown in FIGS. 1A-1C and 2A-2C are rigid and are not bond wires. A gap between the metal members 202, 204 has a distance that ranges from 40 microns to 250 microns, with a distance below this range being disadvantageous because of the resulting high electric fields and the risk of metal smear, and with a distance above this range being disadvantageous because the package becomes unacceptably large.

Various physical features of the substrates 102 (FIGS. 1A-1C and 2A-2C) may be controlled to achieve specific operational outcomes, such as the size of the electric field outside of the capacitors. The electric field should extend only minimally, if at all, beyond the bottom surface 156 of the substrate 102. The size of the electric field is determined by plate size (i.e., the sizes of the metal member pairs that form the plates for capacitors 160, 162, 208, 210, 212, and 214), plate separation, properties of the dielectric 153 (e.g., permittivity), the presence of nearby conductors, the voltage applied to the capacitor, and so on. Such properties are controlled to maintain the electric field within the substrate 102, considering the thickness of the substrate 102 and more specifically, the distance from the capacitor to the bottom surface 156. Assuming a distance from a capacitor 160, 162, 208, 210, 212, or 214 to the bottom surface 156 of 50 microns to 400 microns, the plates of these capacitors are sized between 7x10⁻⁸ m² and 1x10⁻⁵ m², the distance between the plates of the capacitors is between 40 microns and 1000 microns, the relative permittivity of the dielectric 153 is between 3 and 5, the closest conductor to the capacitor is separated from the capacitor by a distance ranging from 40 microns to 200 microns, and the root mean square voltage applied to the capacitor ranges from 0 V to 6000 V, with excursions outside these ranges resulting in the electric field extending beyond the bottom surface 156 and/or an inadequately strong capacitance for the operational objectives of the semiconductor package 100, 200.

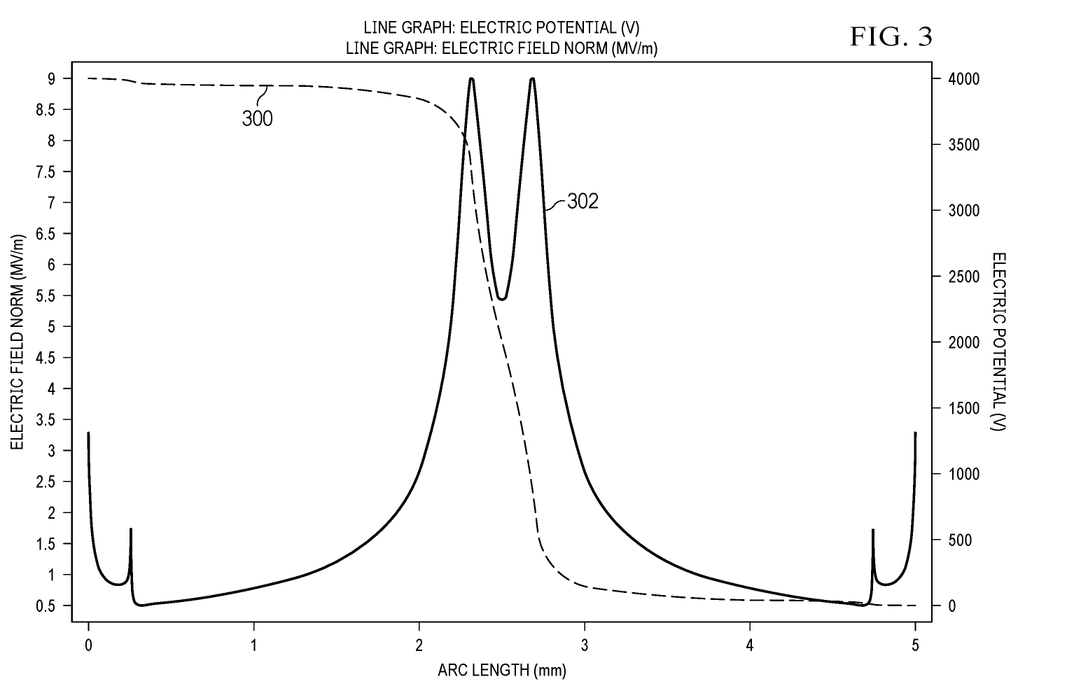

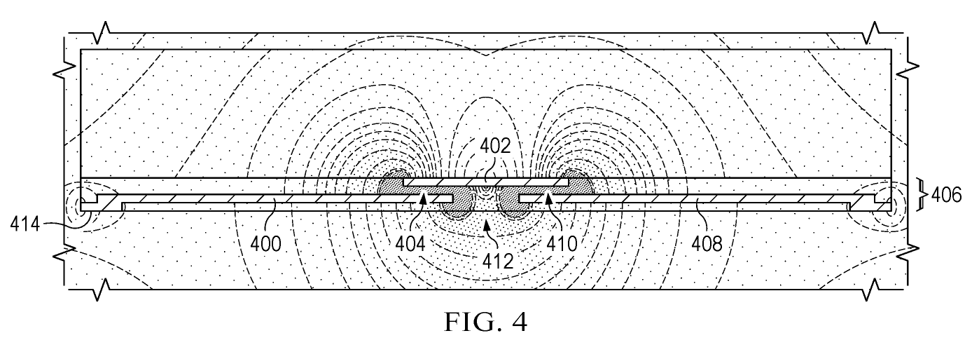

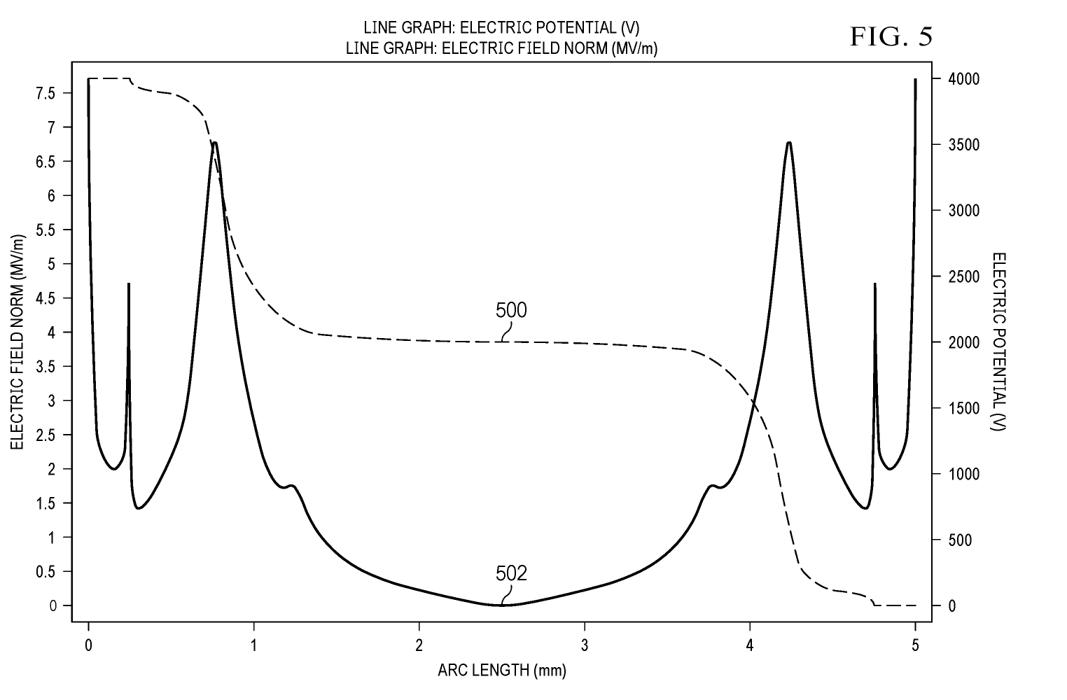

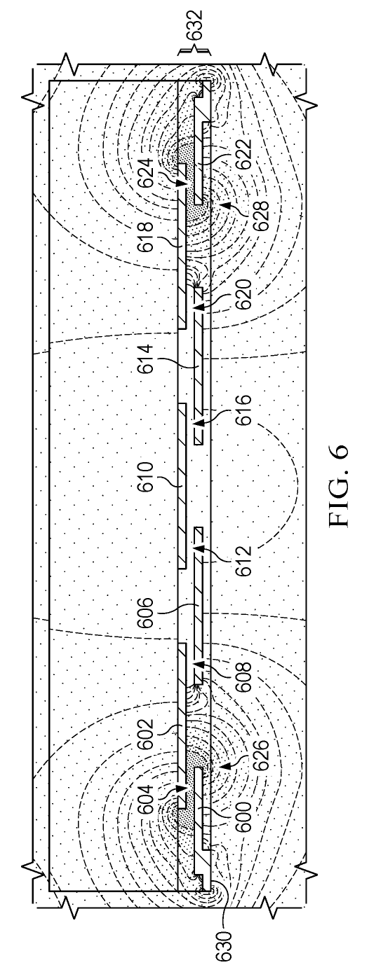

FIGS. 3-6 are graphs and schematic diagrams depicting such electric field behavior in semiconductor packages with fewer capacitors (FIGS. 3 and 4) versus semiconductor packages with more capacitors (FIGS. 5 and 6). In particular, the graph of FIG. 3 includes arc length in millimeters on the x-axis and electric field norm (i.e., magnitude of the electric field vector) in megavolts per meter on the y-axis. The graph also includes electric potential in volts on the y-axis. The graph includes curves 300 and 302. The curve 300 shows the potential distribution under the package (e.g., the package of FIG. 4), and the curve 302 is the electric field generated under the package (e.g., FIG. 4) when a 4000 V isolation voltage is applied between the left and right sides of the package. FIG. 4 provides a profile cross-sectional view of an example semiconductor package in which fewer capacitors (e.g., two capacitors) are included in the substrate. Specifically, metal members 400 and 402 form the plates of a first capacitor 404 in a substrate 406, and metal members 402 and 408 form the plates of a second capacitor 410 in the substrate 406. During operation, the electric fields 412 generated by the capacitors 404, 410 extend well beyond the bottom surface 414 of the substrate 406, as shown. In contrast to the graph of FIG. 3, the graph of FIG. 5 demonstrates how the voltage 500 and electric field 502 are distributed when additional capacitors are introduced in the substrate. Specifically, the axes of the graph in FIG. 5 are the same as the axes of the graph in FIG. 3, but a curve 500 has a smooth transition of voltage distribution indicating a step between arc lengths of 1 mm and 4 mm, and a curve 502 shows lower electric field peaks compared to curve 302 in FIG. 3. The decrease in the electric field value in FIGS. 5 and 6 is about 17% with the additional distributed capacitors, compared to the fewer capacitors of FIGS. 3 and 4. FIG. 6 provides a profile cross-sectional view of an example semiconductor package in which more capacitors (e.g., six capacitors) are included in the substrate. Specifically, metal members 600 and 602 form the plates of a capacitor 604; metal members 602 and 606 form the plates of a capacitor 608; metal members 606 and 610 form the plates of a capacitor 612; metal members 610 and 614 form the plates of a capacitor 616; metal members 614 and 618 form the plates of a capacitor 620; and metal members 618 and 622 form the plates of a capacitor 624. Although electric fields may be generated by any of these capacitors during operation, representative electric fields 626 and 628 are depicted herein. In contrast to the electric fields 412 (FIG. 4), which extend far beyond the bottom surface 414 of the substrate 406, the electric fields 626 and 628 do not extend much beyond a bottom surface 630 of a substrate 632 in which the capacitors 604, 608, 612, 616, 620, and 624 are located.

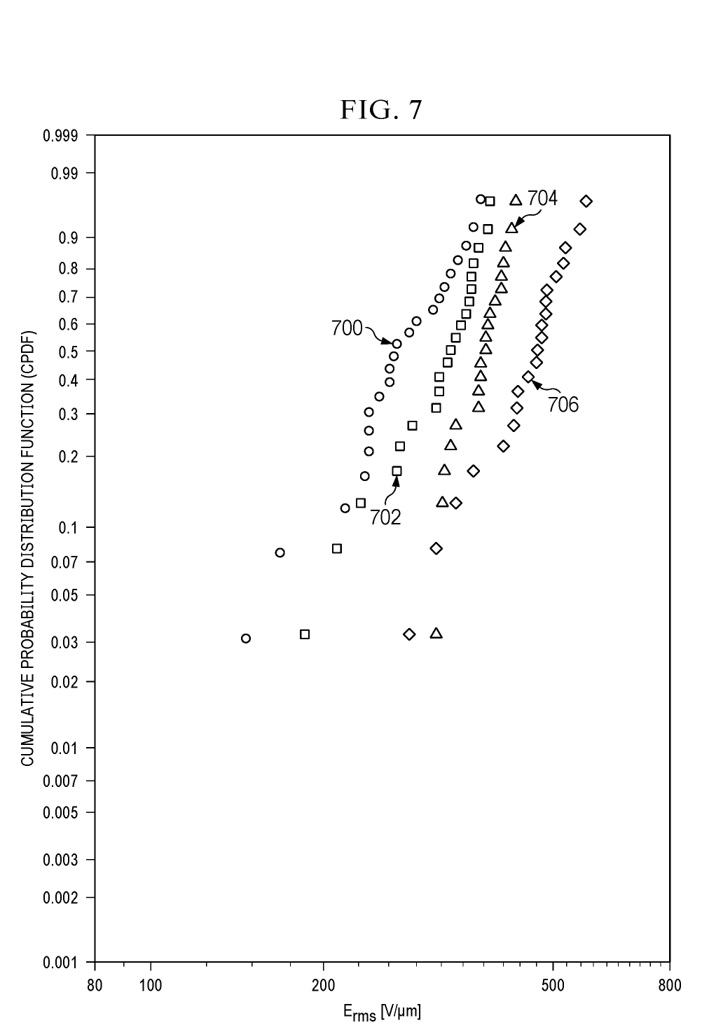

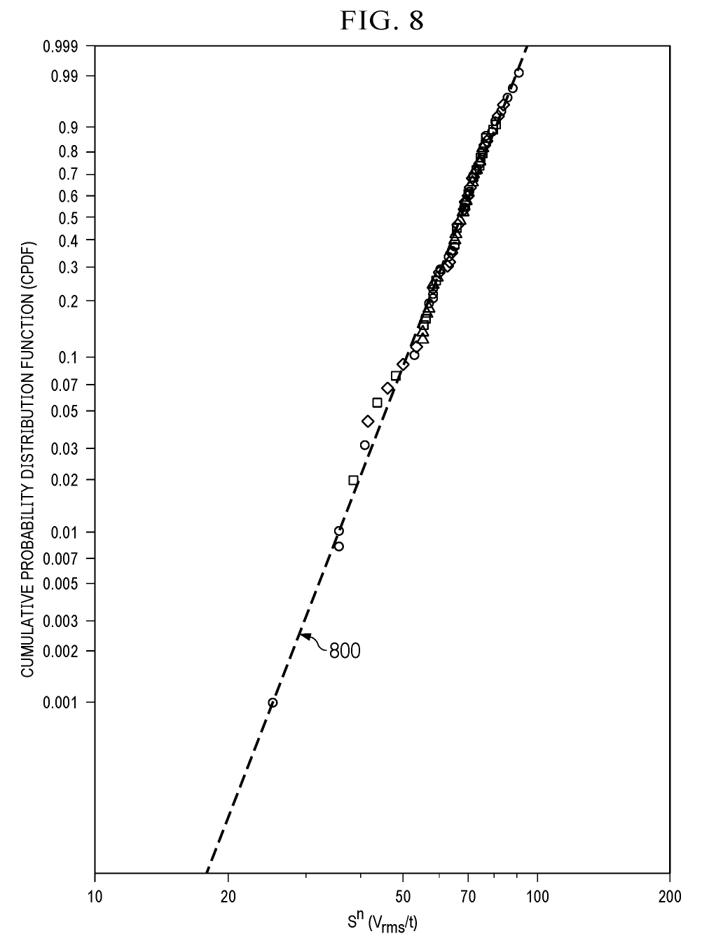

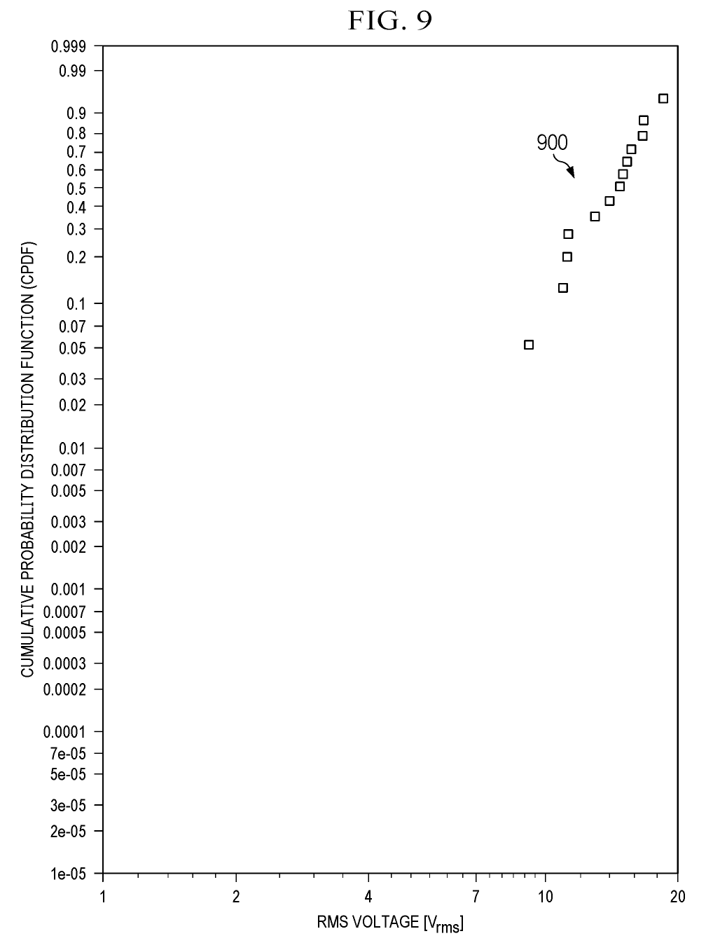

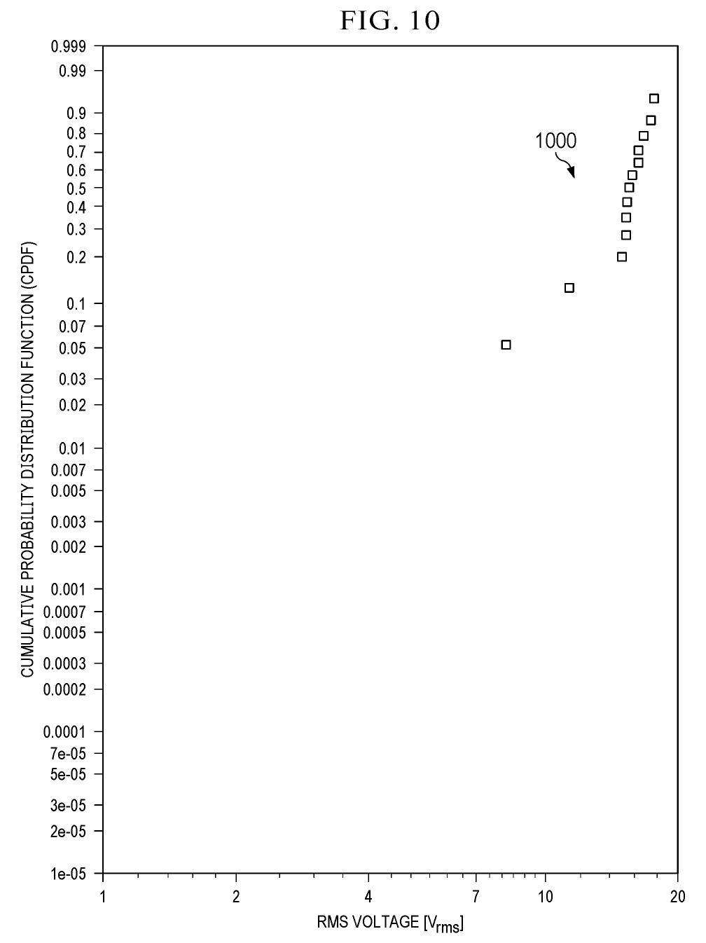

FIGS. 7, 8, 9, and 10 are graphs depicting the behavior of a semiconductor package including metal layer capacitors, in accordance with various examples. In FIG. 7, the x-axis denotes the electric field inside conventional glass fiber reinforced substrate dielectric material, and the y-axis denotes the cumulative probability distribution function (CPDF). A curve 700 indicates a capacitor breakdown value for disk electrodes with a 2200 micron diameter, a curve 702 indicates a capacitor breakdown value for disk electrodes with a 1200 micron diameter, a curve 704 indicates a capacitor breakdown value for disk electrodes with a 700 micron diameter, and a curve 706 indicates a capacitor breakdown value for disk electrodes with a 450 micron diameter. The curves 700, 702, 704, and 706 together demonstrate that breakdown risk is scaled with capacitor size and employed to determine the required capacitance size as a given voltage. In FIG. 8, the x-axis denotes the scaled electric field inside the substrate dielectric material in which the scaling factor S is the area of the electrodes, and the y-axis denotes the cumulative probability distribution function. A curve 800 indicates the best fitted curve. The curve 800 demonstrates that the breakdown values are scaled to determine overall risk for different capacitor designs. In FIG. 9, the x-axis denotes the electric field inside an alternative dielectric material filled with micron-sized silica particles, and the y-axis denotes the cumulative probability distribution function. A curve 900 indicates material dielectric breakdown values. The curve 900 demonstrates the dielectric breakdown risk in using this material for comparison to the substrate material. In FIG. 10, the x-axis denotes the electric field inside an alternative dielectric material filled with micron-sized silica particles, and the y-axis denotes the cumulative probability distribution function. A curve 1000 indicates dielectric breakdown values for the material. The curve 1000 demonstrates the dielectric breakdown risk in using this material for comparison to the substrate material.

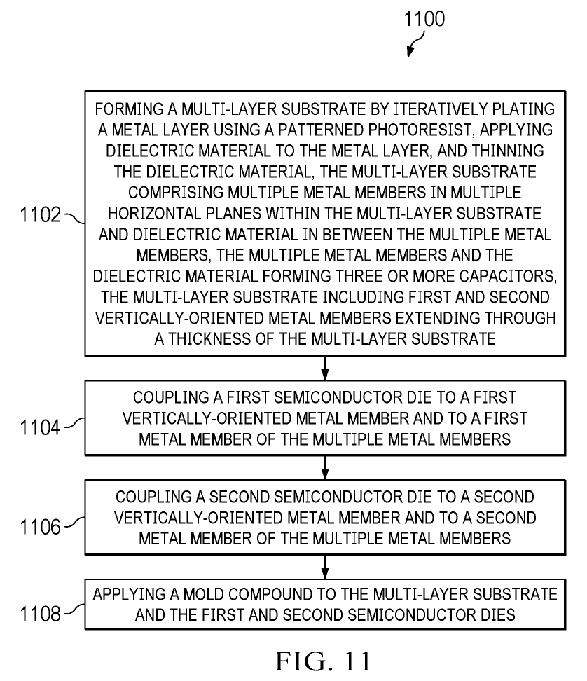

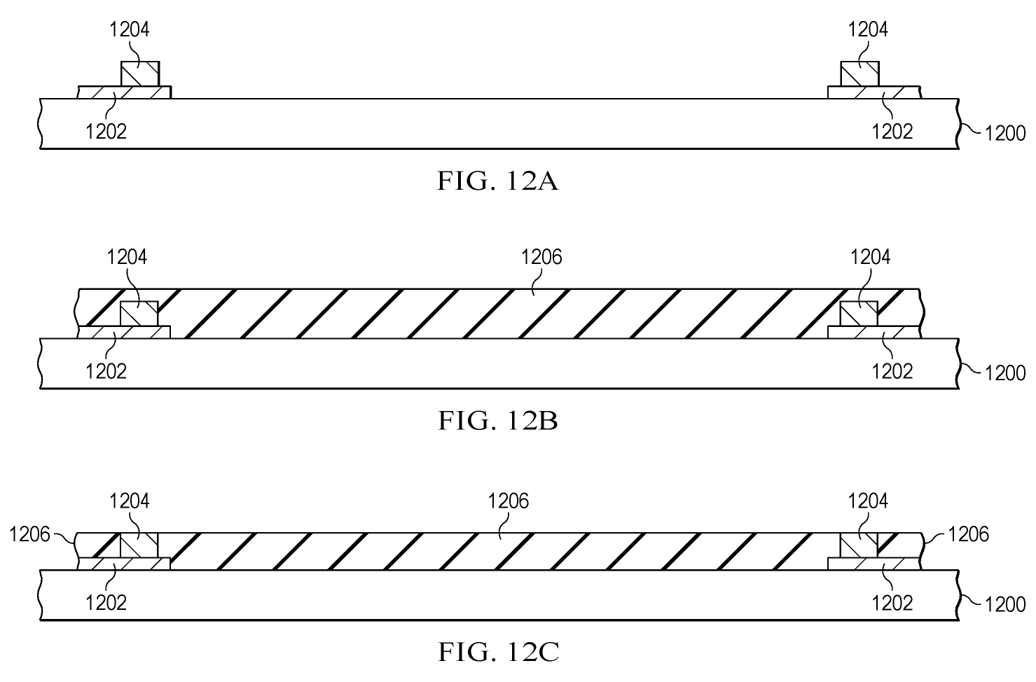

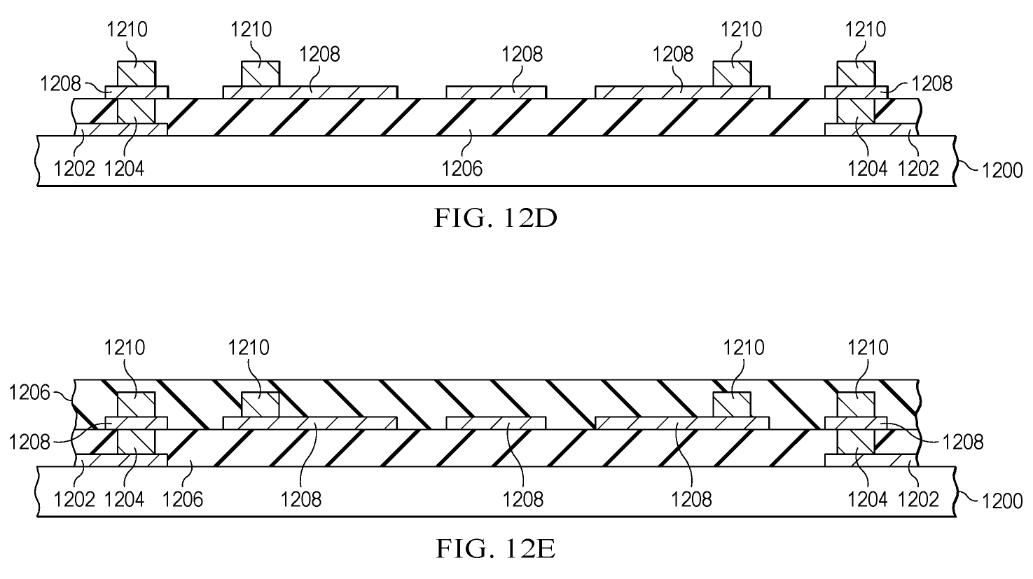

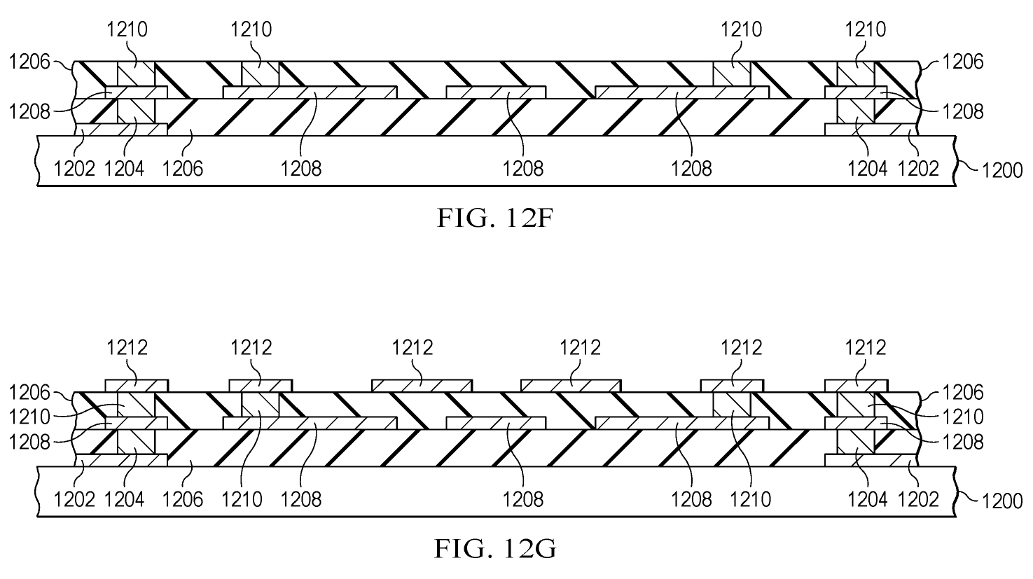

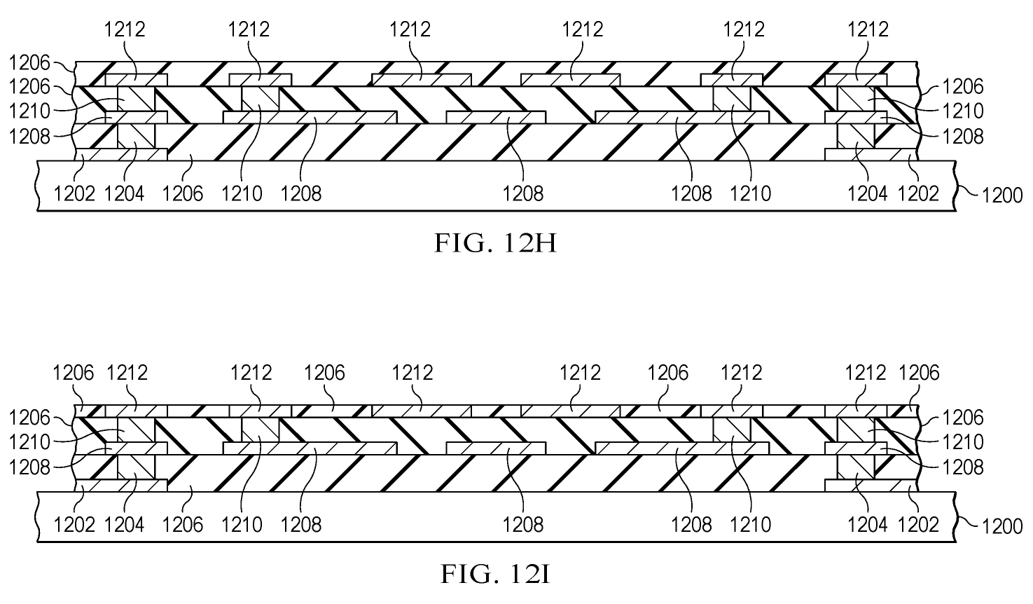

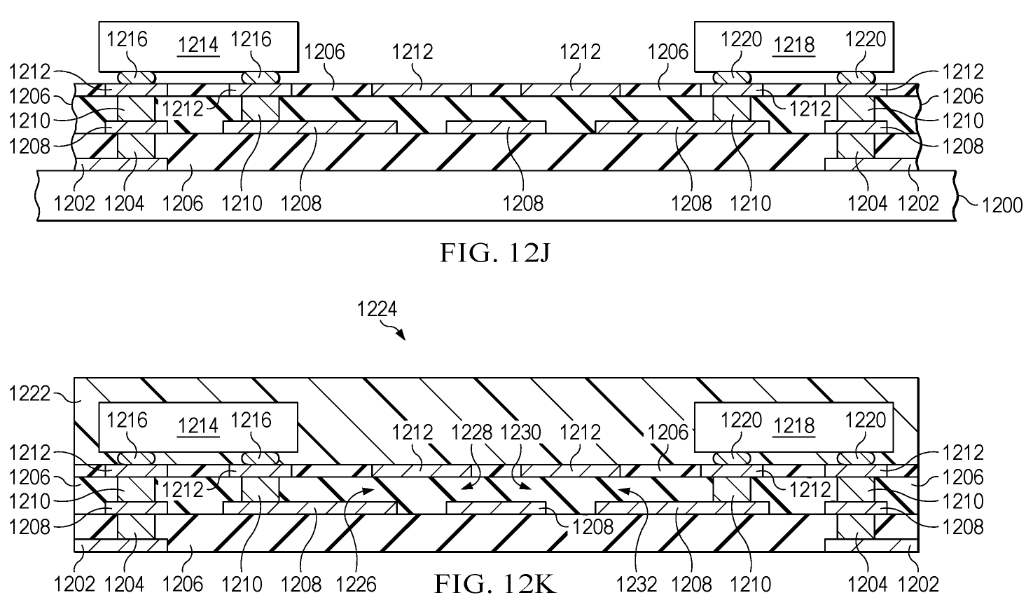

FIG. 11 is a flow diagram of a method 1100 for manufacturing a semiconductor package including metal layer capacitors, in accordance with various examples. FIGS. 12A, 12B, 12C, 12D, 12E, 12F, 12G, 12H, 12I, 12J, and 12K are a process flow of a method for manufacturing a semiconductor package including metal layer capacitors, in accordance with various examples. Accordingly, FIGS. 11 and 12A-12K are now described in parallel with each other.

The method 1100 includes forming a multi-layer substrate by iteratively plating a metal layer using a patterned photoresist, applying dielectric material to the metal layer, and thinning the dielectric material (1102). The multi-layer substrate includes multiple metal members in multiple horizontal planes within the multi-layer substrate and dielectric material in between the multiple metal members (1102). The multiple metal members and the dielectric material form three or more capacitors (1102). The multi-layer substrate includes first and second vertically-oriented metal members extending through a thickness of the multi-layer substrate (1102). FIG. 12A is a profile cross-sectional view of a carrier 1200 on which metal layers 1202 and 1204 are plated. One or more of the metal layers fabricated in step 1102 may be considered to be metal vias, but for simplicity of explanation, all such structures are described here as being parts of metal layers. The metal layers 1202, 1204, as well as other metal layers fabricated in step 1102, may be formed using appropriate photoresist photolithography and metal (e.g., copper) plating techniques. FIG. 12B is a profile cross-sectional view of the structure of FIG. 12A, except that a dielectric 1206 (e.g., ABF) is applied to the metal layers 1202, 1204 and the top surface of the carrier 1200. FIG. 12C is a profile cross-sectional view of the structure of FIG. 12B, except that the dielectric 1206 has been thinned (e.g., grinded) such that the metal layer 1204 is exposed on the top surface of the dielectric 1206. FIG. 12D is a profile cross-sectional view of the structure of FIG. 12C, except that metal layer 1208 has been plated on the metal layer 1204, and metal layer 1210 has been plated on metal layer 1208. FIG. 12E is a profile cross-sectional view of the structure of FIG. 12D, except that additional dielectric 1206 has been applied. FIG. 12F is a profile cross-sectional view of the structure of FIG. 12E, except that the dielectric 1206 has been thinned (e.g., grinded) until the top surface of the metal layer 1210 has been exposed on the top surface of the dielectric 1206. FIG. 12G is a profile cross-sectional view of the structure of FIG. 12F, except that a metal layer 1212 has been plated on the metal layer 1210. FIG. 12H is a profile cross-sectional view of the structure of FIG. 12G, except that additional dielectric 1206 is applied to the metal layer 1212, as shown. FIG. 12I is a profile cross-sectional view of the structure of FIG. 12H, except that the dielectric 1206 has been thinned such that the top surface of the metal layer 1212 is exposed on the top surface of the dielectric 1206. The physical features of the various metal layers fabricated in step 1102 are consistent with the descriptions provided above with respect to FIGS. 1A-1C and 2A-2C.

The method 1100 includes coupling a first semiconductor die to a first vertically-oriented metal member and to a first metal member of the multiple metal members (1104). The method 1100 also includes coupling a second semiconductor die to a second vertically-oriented metal member and to a second metal member of the multiple metal members (1106). FIG. 12J is a profile cross-sectional view of the structure of FIG. 12I, except that a semiconductor die 1214 is coupled to one or more metal members of the metal layer 1212 by solder joints 1216, and a semiconductor die 1218 is coupled to one or more metal members of the metal layer 1212 by solder joints 1220.

The method 1100 includes applying a mold compound to the multi-layer substrate and the first and second semiconductor dies (1108). FIG. 12K is a profile cross-sectional view of the structure of FIG. 12J, except that a mold compound 1222 is applied to the substrate and semiconductor dies depicted in FIG. 12J. Further, the carrier 1200 is removed. The result is a semiconductor package 1224, which includes capacitors 1226, 1228, 1230, and 1232, as shown. The various metal layers of the semiconductor package 1224 extend in the horizontal direction. The semiconductor dies of the semiconductor package 1224 are configured to operate in separate voltage domains, and thus are electrically isolated from each other. In examples, the various metal members shown in FIG. 12K are rigid and are not bond wires.

The method 1100 describes the manufacture of a routable lead frame substrate (RLFS). RLFSs are coreless. In RLFSs, a minimum metal member width (in the horizontal direction) is 30 microns. In RLFSs, the horizontal distance between adjacent metal members in the top view is 40 microns. In RLFSs, the minimum metal layer thickness in the vertical direction is 30 microns. In RLFSs, the minimum dielectric thickness is 30 microns. As shown in FIGS. 12A-12K, in RLFSs, the metal vias have vertical walls, and in some examples, the metal vias are cylindrical. In RLFSs, the dielectric is ABF.

In examples, such as those depicted in FIGS. 1A-1C and 2A-2C, the substrates may be embedded trace substrates (ETSs), in which the vias have a trapezoidal appearance in the profile cross-sectional view, and a circular appearance in a horizontal cross-sectional view. In ETSs, the dielectric layers may include pre-preg. In ETSs, solder masks may be included on the top and bottom surfaces of the substrate. ETSs are coreless. In ETSs, a minimum metal member width (in the horizontal direction) is 8 microns. In ETSs, the horizontal distance between adjacent metal members in the top view is 8 microns. In ETSs, the minimum metal layer thickness in the vertical direction is 12 microns. In ETSs, the minimum dielectric thickness is 18 microns.

Although the semiconductor package substrates described and depicted herein may be described and depicted as being of a particular type (e.g., ETS, RLFS), all possible variations of these substrates are contemplated and expressly included in the scope of this disclosure. For instance, the substrates of FIGS. 1A-1C and 2A-2C may be ETS substrates and/or RLFS substrates, and the substrate in FIG. 12K may be an ETS substrate and/or an RLFS substrate.

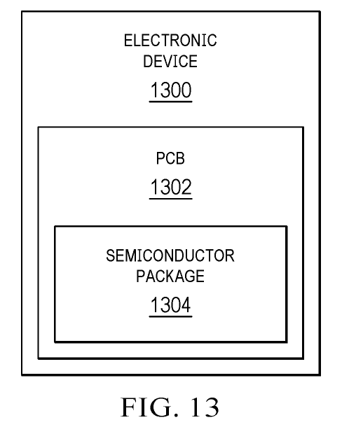

FIG. 13 is a block diagram of an electronic device including a semiconductor package having metal layer capacitors, in accordance with various examples. More specifically, FIG. 13 is a block diagram of an electronic device 1300 (e.g., an automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system) including a printed circuit board (PCB) 1302. A semiconductor package 1304 is coupled to the PCB 1302. The semiconductor package 1304 is representative of the semiconductor packages (e.g., semiconductor packages 100, 200, 1224) described herein.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/- 10 percent of that parameter. Modifications are possible in the described examples, and other examples are possible within the scope of the claims.

What is claimed is:

1. A semiconductor package, comprising:
a first semiconductor die;
a second semiconductor die;
a mold compound covering the first and second semiconductor dies; and
a multi-layer substrate coupled to the first and second semiconductor dies and having a top surface contacting the mold compound, the multi-layer substrate comprising:
a first metal member coupled to the first semiconductor die;
a second metal member coupled to the second semiconductor die, the second metal member coplanar with the first metal member;
a third metal member not physically contacting the first or second metal members, the third metal member co-planar with the first and second metal members;
a fourth metal member not physically contacting the first, second, or third metal members, the fourth metal member closer to the top surface than the first, second, and third metal members;
a fifth metal member not physically contacting the first, second, third, or fourth metal members, the fifth metal member co-planar with the fourth metal member; and
dielectric material in between the first, second, third, fourth, and fifth metal members,
wherein the first and the fourth metal members and the dielectric material form a first capacitor, the third and the fourth metal members and the dielectric material form a second capacitor, the third and the fifth metal members and the dielectric material form a third capacitor, and the second and the fifth metal members and the dielectric material form a fourth capacitor.

2. The semiconductor package of claim 1, wherein the dielectric material comprises a build-up film.

3. The semiconductor package of claim 2, wherein:
the first and second metal members are coupled to the first and second semiconductor dies, respectively, by cylindrical vias,
the semiconductor package is coreless, and
the multi-layer substrate does not contact a solder mask.

4. The semiconductor package of claim 1, wherein the dielectric material comprises pre-preg.

5. The semiconductor package of claim 4, wherein:
the first and second metal members are coupled to the first and second semiconductor dies, respectively, by vias that appear trapezoidal in a profile, cross-sectional view, and
the semiconductor package is coreless.

6. The semiconductor package of claim 1, wherein the first, second, third, fourth, and fifth metal members are not bond wires.

7. The semiconductor package of claim 1, wherein the fourth and fifth metal members are separated by a distance ranging from 40 microns to 250 microns.

8. The semiconductor package of claim 1, wherein each of the first, second, third, fourth, and fifth metal members has a thickness of at least 12 microns.

9. The semiconductor package of claim 1, wherein the first semiconductor die is configured to operate in a first voltage domain and the second semiconductor die is configured to operate in a second voltage domain, the first and second semiconductor dies electrically isolated from each other.

10. A semiconductor package, comprising:
a first semiconductor die;
a second semiconductor die;
a mold compound covering the first and second semiconductor dies; and
a multi-layer substrate coupled to the first and second semiconductor dies and having a top surface contacting the mold compound, the multi-layer substrate comprising multiple metal members in multiple horizontal planes within the multi-layer substrate and dielectric material in between the multiple metal members, the multiple metal members and the dielectric material forming multiple capacitors.

11. The semiconductor package of claim 10, wherein the dielectric material comprises one of a build-up film and a pre-preg material.

12. The semiconductor package of claim 10, wherein first and second metal members of the multiple metal members are separated by a distance ranging from 40 microns to 250 microns, the first and second metal members in a same horizontal plane.

13. The semiconductor package of claim 10, wherein the first semiconductor die is configured to operate in a first voltage domain and the second semiconductor die is configured to operate in a second voltage domain, the first and second semiconductor dies electrically isolated from each other.

14. The semiconductor package of claim 10, wherein each of the multiple metal members has a thickness of at least 12 microns.

15. The semiconductor package of claim 10, further comprising an additional metal member in the multi-layer substrate and a metal via coupled to the additional metal member, wherein the metal via has a cylindrical shape or a trapezoidal shape in a profile cross-sectional view.

16. A method for manufacturing a semiconductor package, comprising:
forming a multi-layer substrate by iteratively plating a metal layer using a patterned photoresist, applying dielectric material to the metal layer, and thinning the dielectric material, the multi-layer substrate comprising multiple metal members in multiple horizontal planes within the multi-layer substrate and the dielectric material in between the multiple metal members, the multiple metal members and the dielectric material forming multiple capacitors;
coupling a first semiconductor die to the multi-layer substrate;
coupling a second semiconductor die to the multi-layer substrate ; and
applying a mold compound to the multi-layer substrate and the first and second semiconductor dies.

17. The method of claim 16, wherein the first and second semiconductor dies are electrically isolated from each other.

18. The method of claim 16, wherein the dielectric material comprises a build-up film.

19. The method of claim 16, wherein first and second metal members of the multiple metal members are separated by a distance ranging from 40 microns to 250 microns, the first and second metal members in a same horizontal plane.

20. The method of claim 16, wherein each of the multiple metal members has a thickness of at least 12 microns.
